(19) United States
(12) Patent Application Publication
(10) Pub. No.: US 2002/0058357 A1
(43) Pub. Date: May 16, 2002

(54) Die attaching method

(75) Inventor: Chin-Huang Chang, Tai-Ping City (TW)

Correspondence Address: KLARQUIST SPARKMAN, LLP, 121 SW SALMON STREET, SUITE 1600, PORTLAND, OR, 97204, US

(73) Assignee: Siliconware Precision Industries Co., Ltd.

(21) Appl. No.: 10/040,865

(22) Filed: Dec. 27, 2001

Related U.S. Application Data
(63) Continuation-in-part of application No. 09/570,513, filed on May 16, 2000.

(51) Int. Cl. H01L 21/44; H01L 21/48; H01L 21/50

(52) U.S. Cl. 438/118; 438/109

(57) ABSTRACT

The present invention relates to a method of attaching at least a die to a predetermined portion of an object, where the object may be a lead frame or a substrate or any entity capable of carrying the die or electrically connecting the die. The method provided by the present invention is characterized by taking advantage of a feature of the half-cured adhesive paste used for connecting a die to a predetermined portion of an object. The process of attaching the die to the object is thus immunized against the undesirable paste spilling inherent in conventional die attaching process. The superiority of the present invention to conventional arts is particularly significant when it is applied to attaching a Daughter-die to a Mother-die that has been attached to an object.

This is a continuation-in-part of application Ser. No. 09/570,513 filed on May 16, 2000.

### FIELD OF THE INVENTION

The present invention relates to a method of attaching a die to a predetermined portion of an object, particularly to a method of attaching a daughter-die to a mother-die which has been attached to a substrate or a lead frame.

### BACKGROUND OF THE INVENTION

According to conventional Die Attaching methods in which paste is used for connecting a die and an object, the paste is usually dispensed onto a predetermined portion of a substrate or a lead frame, and at least a die is then placed on the paste in order to attach the die to the predetermined portion of the substrate or the lead frame. A disadvantage of such methods is the extreme difficulty in controlling Fillet height, Bond-line thickness, and paste spilling area. The disadvantage is particularly serious when attaching a daughter-die to a mother-die having been attached to, an object. Illustrated in FIG. 1 is a typical conventional method for attaching a daughter-die 11 to a mother-die 10 which has been attached to a substrate 12, where there is spilling paste to an extent as shown by 13, resulting in impracticability bonding wire 15 onto mother-die 10. As also can be seen from FIG. 1, Fillet height is so difficult to control that it reaches an extent shown by point 14. A new scheme is therefore suggested by the present invention to immunize die attaching processes against the disadvantage inherent in conventional Die Attaching methods, thereby to enable easier process of packaging Stacked-Chips, and to assure quality of related products.

### SUMMARY OF THE INVENTION

An object of the present invention is to provide a method of attaching at least a die to an object, in order to immunize die attaching processes against undesirable paste spilling area, and thereby to enable smooth and easier process of packaging Stacked-Chips, and to assure stable quality of related products.

Another object of the present invention is to provide schemes for realizing optimum bond-line thickness and bubble-free paste layer (the layer formed by the paste between a die and an object after the die is attached to the object). The die packaged on the basis of such schemes can be immunized against delamination or die crack.

An aspect of the present invention is a method for attaching at least a die to a predetermined portion of an object, which comprises the following steps:

spreading adhesive paste onto the backside of a wafer;

half-curing the adhesive paste;

dividing the wafer into a plurality of dice after half-curing the adhesive paste;

heating the predetermined portion of the object; and

setting at least one die of the dice in such a way that the die's side which has the adhesive paste contacts the predetermined portion of the object. Here the step of half-curing adhesive paste means that the adhesive paste is heated until it is at a temperature which is higher environmental temperature while is not high enough for cross linking of the molecules of the adhesive paste. It is an option to dry the adhesive paste when heating the adhesive paste or after heating the adhesive paste. Drying the adhesive paste may be implemented by at least one way selected from among spontaneous air drying and artificial drying. Usually the step of half-curing the adhesive paste is performed by heating the adhesive paste until its temperature is in the middle part of the range between environmental temperature and the temperature for cross linking of the molecules of the adhesive paste, with an option to let the adhesive paste dried when heating the adhesive paste. Drying the adhesive paste may also take place when and after heating the adhesive paste. For example, if environmental temperature is 25° C. and the temperature for cross linking of the molecules of the adhesive paste is 225° C., the adhesive paste may be heated to reach a temperature ranging between 100° C. and 150° C. It is preferred the step of heating the predetermined portion of the object is such that the adhesive paste, when or after the die's side which has the adhesive paste contacts the predetermined portion of the object, reaches a temperature for cross linking of the molecules of the adhesive paste.

It must be noted that the above step of dividing the wafer into a plurality of dice after or when half-curing adhesive paste is a special feature of the present invention, which realizes controlling bond-line thickness and achieving bubble free adhesive layer. In conventional arts of die attaching process, adhesive paste is always cured to be in a state of normal adhesion so that its application can match conventional steps which are based on conventional knowledge or common sense. The state of normal adhesion of adhesive paste can be reached only when the paste is heated to reach a temperature high enough for cross linking of the molecules of the paste. The present invention, however, breaks through conventional knowledge or common sense to provide a step of half-curing the adhesive paste on the backside of a wafer, particularly a step of half-curing adhesive paste before dividing the wafer into a plurality of dice, resulting in a unique feature of realizing controlling bond-line thickness and achieving bubble free adhesive layer.

It must also be noted that if paste of B-stage type is used as the adhesive paste in combination with the step of dividing the wafer into a plurality of dice after or when half-curing adhesive paste, both the undesirable Fillet height and paste spilling area inherent in conventional processes of die attaching using paste can be significantly controlled to be within a tolerable range, leading to another special feature of the present invention.

If the adhesive paste is spread onto the backside of wafer by screen printing such as using screen printing sheet, Bond-line thickness can be further better or easily controlled.

The above special features of the present invention result from the unique combination of steps arranged by the present invention, particularly when adoption of adhesive paste of B-stage type is associated with these steps. As no any prior art has ever suggested the combination of these steps or the association of these steps with adhesive paste of B-stage type to provide these features, the present invention is thus intended for these features by which bubble free adhesive layer can be realized, bond-line thickness and the undesirable Fillet height as well as paste spilling area all inherent in prior arts can be significantly controlled to be within a tolerable range. The reduction of paste spilling area achieved by the present invention is particularly significant for the process in which a Daughter-die is to be attached to a Mother-die that has been attached to an object such as a substrate or a lead frame. In conventional arts, the paste spilling area on a Mother-die resulting from attaching a Daughter-die to the Mother-die is always such that the wire bonding between the Mother-die and the substrate faces tremendous difficulty.

Another aspect of a method provided by the present invention for attaching at least a die to a predetermined portion of an object, comprises the steps of:

letting one side of the die contaminated by adhesive paste;

half-curing the adhesive paste;

heating the predetermined portion of the object; and

setting the die in such a way that the die's side which has the adhesive paste contacts the predetermined portion of the object. Here if the adhesive paste on one side of the die is paste of B-stage type, and is half-cured before contacting the predetermined portion of the object, the present invention can also provide special features such as bubble free adhesive layer realizable, and bond-line thickness, undesirable Fillet height as well as paste spilling area all controllable to be within a tolerable range. It is preferred the step of heating the predetermined portion of the object is such that the adhesive paste, when or after the die's side which has the adhesive paste contacts the predetermined portion of the object, reaches a temperature for cross linking of the molecules of the adhesive paste.

The present invention may best be understood through the following description with reference to the accompanying drawings, in which:

### BRIEF DESCRIPTION OF THE DRAWINGS

FIG. 1 shows undesirable paste spilling area inherent in conventional die attaching methods, which inevitably leads to difficult wire bonding.

FIG. 2 shows a process of spreading paste onto the backside of a wafer according to an embodiment of the present invention.

FIG. 3 shows a wafer divided according to an embodiment of the present invention.

FIG. 4 shows a die being picked up according to an embodiment of the present invention.

FIG. 5 shows a process suggested by an embodiment of the present invention for attaching a die to a predetermined portion of an object.

FIG. 6 shows a process suggested by an embodiment of the present invention for attaching a die to a mother-die.

FIG. 7 shows a product made according to an embodiment of the present invention.

### DETAILED DESCRIPTION OF THE PREFERRED EMBODIMENTS

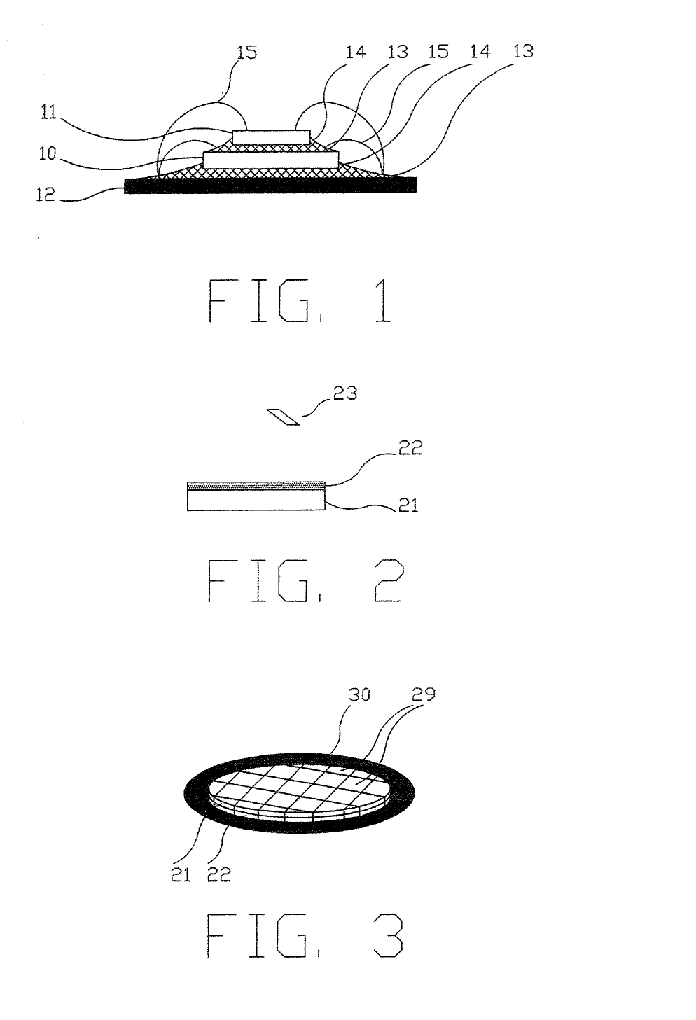

A method provided by the present invention for attaching at least a die to a predetermined portion of an object, is now illustrated by referring to FIGS. 2, 3, 4, and 5. The method comprises the steps of: spreading adhesive paste 22 onto the backside of a wafer 21; half-curing the adhesive paste 22; dividing the wafer 21 into a plurality of dice 29; heating a predetermined portion 40 of an object 60; and setting at least one die of the dice 29 in such a way that the die's side which has the adhesive paste 22 contacts the predetermined portion 40 of the object 60. If the above step of half-curing the adhesive paste is performed before dividing the wafer 21 into a plurality of dice 29, optimum Bond-line thickness and bubble free adhesive layer (or paste layer) structure can be achieved, certainly leading to the quality promotion of products thus packaged. Furthermore in case the adhesive paste 22 is paste of B-stage type, and the dividing of wafer 21 is done after the adhesive paste 22 is half-cured, i.e., the adhesive paste 22 is paste of B-stage type, and the step of half-curing the adhesive paste is performed before dividing the wafer 21 into a plurality of dice, both the undesirable Fillet height and paste spilling area inherent in conventional processes of attaching a die to an object by using paste can be significantly controlled to be within a tolerable range. The adhesive paste 22 is spread onto the backside of wafer 21 preferably by screen printing such as using screen printing sheet 23 in order to better or easily control Bond-line thickness. That the adhesive paste 22 on the backside of wafer 21 is half-cured means that the adhesive paste 22 on the backside of wafer 21 is heated until it is at a temperature higher than environmental temperature while is not high enough for cross linking of the molecules of the paste. Drying of the adhesive paste may take place when or after the adhesive paste reaches the temperature. A preferred way of letting the adhesive paste on the backside of wafer 21 half-cured may be simply to heat the paste to reach a temperature which is about half of that for cross linking of the molecules of the paste. Drying the paste may be by spontaneous air drying and/or artificial drying.

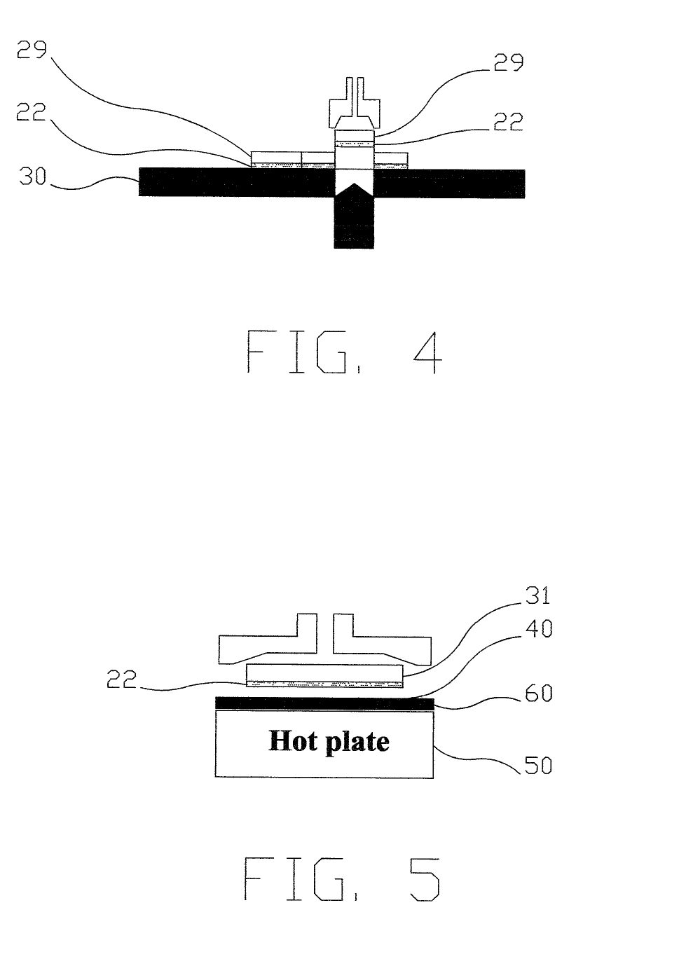

In FIG. 3, wafer carrier 30 supports wafer 21 so that wafer 21 can be conveniently divided into a plurality of dice 29.

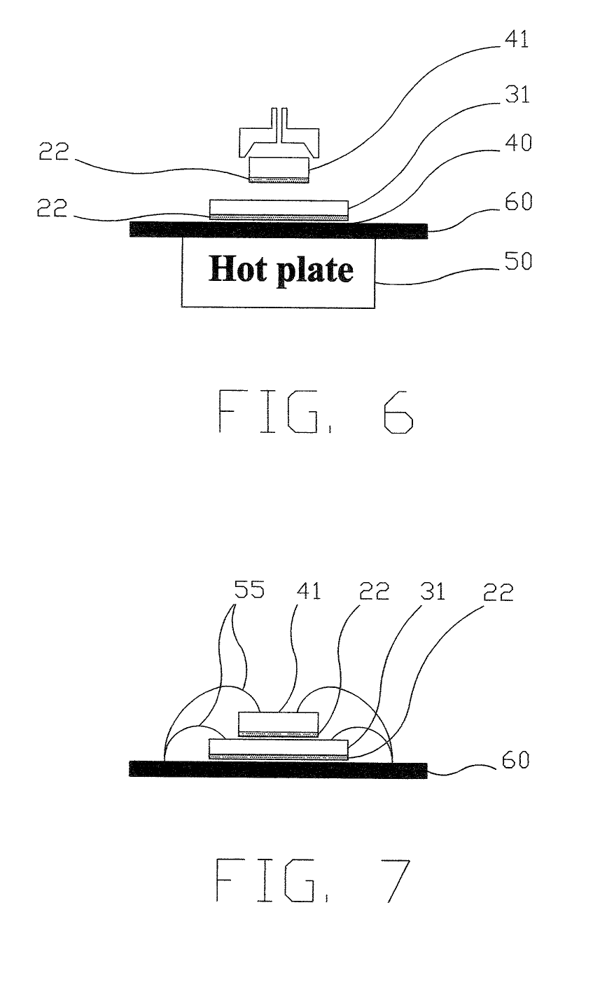

In FIG. 4, one die of dice 29 which has adhesive paste 22 on one side thereof is picked up from wafer carrier 30, and is then set in such a way that its side which has adhesive paste 22 thereon contacts a predetermined portion 40 of a substrate 60 shown in FIG. 5. The die so set to attach to the substrate 60 is called mother-die 31. The predetermined portion 40 of the substrate 60 in FIG. 5 is heated by a hot plate 50 before the mother-die 31 is placed thereon. In FIG. 6, another die 41 (called daughter die) which was picked up from wafer carrier 30 as shown in FIG. 4 is placed onto mother-die 31 that has been attached to substrate 60 as shown in FIG. 5. After daughter-die 41 is placed on mother-die 31 as shown in FIG. 6, wire bonding is performed, when half-curing paste 22 is done, to form bonding wires 55 as shown in FIG. 7. Shown in FIG. 7 is the product thus obtained. Due to easier controlling of paste spilling realized by the die attaching method provided by the present invention, there can be no undesirable paste spilling area on the portion of mother-die 31 where wire bonding shall be performed, thereby wire bonding on mother-die 31 can be smoothly done, and the process of packaging Stacked-Chips becomes easier with product quality control more reliable. Furthermore the Fillet height and Bond-line thickness formed according to the die attaching method provided by the present invention can be well controlled, and quality of products thus made can therefore be significantly promoted.

The aforementioned paste 22 may be electrically nonconductive material, or be mixed with electrically conductive material to become electrically conductive. The step of letting the paste on the backside of wafer 21 half-cured before wafer 21 is divided into a plurality of dice 29 enables the die attaching process to achieve optimum Bond-line thickness and bubble free paste layer structure, certainly leading to the quality promotion of products thus packaged. As aforementioned, letting the paste on the backside of wafer 21 half-cured means that the paste on the backside of wafer 21 is heated until its temperature is higher than environmental temperature while is not high enough for cross linking of the molecules of the paste. Its drying takes place when or after proceeding the heating.

If the aforementioned paste 22 includes material providing good wettability for connecting the predetermined portion 40 of the object, the smoothness of the die attaching process and the product thus made can be further promoted.

The application of the die attaching method provided by the present invention is not limited to attaching at least a die to a substrate or another die, it also fits the process of attaching at least a die to a lead frame or to any object capable of carrying a die or electrically connecting a die.

According to the aforementioned die attaching method, the way of heating the predetermined portion 40 of the substrate is not limited to the one shown in FIG. 5, it may be whatever scheme as long as the temperature of the predetermined portion 40 can be raised.

In the aforementioned die attaching method provided by the present invention, the mother-die 31 may be so set that its side which has paste 22 thereon contacts the predetermined portion 40 (please refer to FIG. 5) with pressure, in order to further promote quality of the attaching. The process with pressure applied to the contacting between mother-die 31 and the predetermined portion 40 may also fit the process of attaching daughter die 41 to mother-die 31 (please refer to FIG. 6).

It shall be understood from the above illustrations that the spirit of the present invention is not limited to the aforementioned embodiments, instead it may be embodied to comprise the steps of: letting one side of a die contaminated by adhesive paste; letting the adhesive paste half-cured; and setting the die in such a way that the die's side which has adhesive paste contacts a heated portion of an object. It can be seen now the present invention may also be embodied as a method comprising the following steps for attaching at least a die to a predetermined portion of an object:

contaminating one side of the die by adhesive paste;

half-curing the paste on one side of the die;

heating the predetermined portion of the object; and

setting the die in such a way that the diets side which has adhesive paste contacts the predetermined portion of the object.

It shall also be understood that the aforementioned adhesive paste may be printed onto one side of the die, therefore the present invention may also be embodied as a method comprising the following steps for attaching at least a die to a predetermined portion of an object:

printing adhesive paste onto one side of the die;

half-curing the paste on one side of the die;

heating the predetermined portion of the object; and

setting the die in such a way that the die's side which has adhesive paste contacts the predetermined portion of the object.

While the invention has been described in terms of what are presently considered to be the most preferred embodiments, it shall be understood that the invention needs not be limited to the disclosure. On the contrary, it shall be construed to cover various modifications and similar arrangements as well as any schemes included within the spirit and scope of the appended claims.

What is claimed is:

1. A method for attaching at least a die to a predetermined portion of an object, comprising the steps of:
spreading adhesive paste onto the backside of a wafer;
half-curing said adhesive paste;
dividing the wafer into a plurality of dice after half-curing said adhesive paste;
heating the predetermined portion of said object; and
setting at least one die of said dice in such a way that the die's side which has said adhesive paste contacts the predetermined portion of said object, wherein the step of half-curing said adhesive paste before dividing the wafer into a plurality of dice is for controlling bond-line thickness and achieving bubble free adhesive layer.

2. The method according to claim 1 further comprising a step of setting at least another one die of said dice in such a way that said another one die's side which has said adhesive paste contacts a side of a die which has been attached to the predetermined portion of said object.

3. The method according to claim 1 wherein paste of B-stage type is used as said adhesive paste, to control fillet height and adhesive paste spilling area.

4. The method according to claim 1 further comprising a step of bonding at least a wire between said object and the die which has contacted the predetermined portion of said object, for electrically connecting said object and the die which has contacted the predetermined portion of said object.

5. The method according to claim 1 wherein said adhesive paste includes material providing wettability for connecting the predetermined portion of said object.

6. The method according to claim 1 wherein the predetermined portion of said object is heated by a hot plate nearby.

7. The method according to claim 1 wherein said object is selected from among a substrate and a lead frame.

8. The method according to claim 1 wherein said object is another die.

9. The method according to claim 1 wherein the step of spreading said adhesive paste onto the backside of said wafer is performed by screen printing, for controlling Bond-line thickness.

10. The method according to claim 1 wherein the step of heating the predetermined portion of the object is such that the adhesive paste, when the die's side which has the adhesive paste contacts the predetermined portion of the object, reaches a temperature for cross linking of the molecules of the adhesive paste.

11. The method according to claim 1 wherein the step of half-curing said adhesive paste includes the step of heating said adhesive paste to be at a temperature higher than environmental temperature while lower than that for cross linking of the molecules of the paste.

12. The method according to claim 1 wherein the step of half-curing said adhesive paste includes the step of heating said adhesive paste to be at a temperature which is in the middle part of the range between environmental temperature and the temperature for cross linking of the molecules of the paste.

13. The method according to claim 2 further comprising the steps of bonding at least a wire between said object and the die which has contacted the predetermined portion of said object, for electrically connecting said object and the die having contacted the predetermined portion of said object; and bonding at least a wire between said object and said another one die which has contacted the predetermined portion of said object, for electrically connecting said object and said another one die which has contacted the predetermined portion of said object.

14. A method for attaching at least a die to a predetermined portion of an object, comprising the steps of:
spreading adhesive paste onto the backside of a wafer;
half-curing said adhesive paste;
dividing the wafer into a plurality of dice after half-curing said adhesive paste;
heating the predetermined portion of said object;
setting at least one die of said dice in such a way that the die's side which has said adhesive paste contacts the predetermined portion of said object; and
setting at least another one die of said dice in such a way that said another one die's side which has said adhesive paste contacts a side of a die which has been attached to the predetermined portion of said object, wherein the step of half-curing said adhesive paste before dividing the wafer into a plurality of dice is for controlling bond-line thickness and achieving bubble free adhesive layer.

15. The method according to claim 14 further comprising the steps of bonding at least a wire between said object and the die which has contacted the predetermined portion of said object, for electrically connecting said object and the die having contacted the predetermined portion of said object; and bonding at least a wire between said object and said another one die which has contacted the predetermined portion of said object, for electrically connecting said object and said another one die which has contacted the predetermined portion of said object.

16. A method for attaching at least a die to a predetermined portion of an object, comprising the steps of:
letting one side of said die contaminated by adhesive paste;
half-curing said adhesive paste;
heating the predetermined portion of said object; and
setting said die in such a way that the die's side which has said adhesive paste contacts the predetermined portion of said object, wherein the step of half-curing said adhesive paste is for controlling bond-line thickness and achieving bubble free adhesive layer.

17. The method according to claim 16 further comprising the steps of:
letting one side of another one die contaminated by adhesive paste;
half-curing the adhesive paste on one side of said another one die; and setting said another one die in such a way that said another one die's side which has the half-cured adhesive paste contacts said die that has contacted the predetermined portion of said object.

18. The method according to claim 16 wherein paste of B-stage type is used as said adhesive paste, to control fillet height and adhesive paste spilling area.

19. The method according to claim 16 further comprising a step of bonding at least a wire between said object and the die which has contacted the predetermined portion of said object, for electrically connecting said object and the die having contacted the predetermined portion of said object.

20. The method according to claim 17 further comprising a step of bonding at least a wire between said object and said another one die which has contacted the predetermined portion of said object, for electrically connecting said object and said another one die which has contacted the predetermined portion of said object.
